(19) United States
(12) Patent Application Publication
(10) Pub. No.: US 2022/0418140 A1
(43) Pub. Date: Dec. 29, 2022

(54) LOCKING AND FIXING DEVICE, AND SERVER

(71) Applicant: INSPUR SUZHOU INTELLIGENT TECHNOLOGY CO., LTD., Suzhou, Jiangsu (CN)

(72) Inventor: Sheng ZHANG, Suzhou, Jiangsu (CN)

(21) Appl. No.: 17/780,562

(22) PCT Filed: Apr. 27, 2020
(86) PCT No.: PCT/CN2020/087155

§ 371 Date: May 27, 2022

(30) Foreign Application Priority Data
Jan. 7, 2020 (CN) 202010014409.4

(51) Int. Cl. H05K 7/14

(52) U.S. Cl. CPC H05K 7/1431; H05K 7/1487

(57) ABSTRACT

A locking and fixing device, and a server, the locking and fixing device comprises a mounting frame and an expansion card assembly, and the expansion card assembly is mounted on the mounting frame; the locking and fixing device further comprises: a lock mechanism, wherein the mounting frame is provided with a hinge part and a mating part; and one end of the lock mechanism facing the hinge part is hinged to the hinge part, and one end facing away from the hinge part is openably and closably locked on the mating part, so as to lock the mounting frame and the expansion card assembly together.

### CROSS-REFERENCE TO RELATED APPLICATION

This application claims priority to Chinese Patent Application No. 202010014409.4, filed on Jan. 7, 2020 in China National Intellectual Property Administration and entitled “LOCKING AND FIXING DEVICE, AND SERVER”, which is hereby incorporated by reference in its entirety.

### FIELD

The present application relates to the field of communication devices, in particular to a locking and fixing device, and a server.

### BACKGROUND

Existing servers include mounting frames, expansion cards, and stop pieces. The stop piece and expansion card are assembled first, and then assembled on the mounting frame together. Finally, the stop piece is locked on the mounting frame trough a screw to fix the mounting frame, the expansion card, and the stop piece together.

By this fixing method, a necessary locking tool is required in the screw locking process which cannot be achieved manually alone. The problem of breakage may also occur during the screw locking process. Furthermore, when there are many expansion cards, the entire screw locking process will also consume more time and manpower. Furthermore, if a screw is not tight enough, during long-distance transportation of the server, the screw can be loosened due to the road condition or loading and unloading, and the like, and even worse, the screw may fall off or be lost. After long-time use, the screw is also prone to failure, etc. All these may affect the usability of the server.

### SUMMARY

The present application provides a locking and fixing device, which is convenient for assembling, fixing, and removal, and can maintain the usability for long time. The present application further provides a server.

The locking and fixing device provided in an embodiment of the present application includes a mounting frame and an expansion card assembly. The expansion card assembly is mounted on the mounting frame; the locking and fixing device further includes: a lock mechanism. The mounting frame is provided with a hinge part and a mating part; and one end of the lock mechanism facing the hinge part is hinged to the hinge part, and one end facing away from the hinge part is openably and closably locked on the mating part, so as to lock the mounting frame and the expansion card assembly together.

Optionally, the lock mechanism includes a fixing member, one end of which facing the hinge part is hinged to the hinge part; a lock catch movably mounted on the fixing member and assembled with the fixing member, wherein one end of the lock catch facing away from the hinge part is provided with a spring bolt, and the spring bolt and the mating part are locked with each other; and an elastic member for resetting arranged between the fixing member and the lock catch. Optionally, a side surface of the lock catch facing the fixing member is provided with a mounting slot; the elastic member is located in the mounting slot; a protruding stop plate is arranged on the fixing member; and the stop plate extends into the mounting slot; wherein one end of the elastic member facing the spring bolt is abutted against a slot wall of the mounting slot, and one end of the elastic member facing away from the spring bolt is abutted against the stop plate.

Optionally, a side surface of the fixing member facing the lock catch is provided with an elongated accommodating slot; the lock catch is movably mounted in the elongated accommodating slot; a through hole is formed in a side wall of one end of the elongated accommodating slot facing away from the hinge part; and the spring bolt extends out of the through hole and is locked on the mating part.

Optionally, a guide rail elongated slot is formed in a side wall of the elongated accommodating slot adjacent to the through hole; a guide block is provided on the lock catch; and the guide block extends into the guide rail elongated slot to guide a reciprocating linear movement of the lock catch.

Optionally, two or four groups of the guide rail elongated slots and the guide blocks are symmetrically disposed. Optionally, a side surface of the lock catch facing away from the fixing member is provided with an operation part and an operation indication identifier.

Optionally, side surfaces of the spring bolt and the guide block facing the fixing member are guide bevels.

Optionally, the operation part is a boss or a groove.

Optionally, a side surface of the fixing member facing away from the lock catch is provided with an elastic convex rib, and the elastic convex rib presses the expansion card assembly against the mounting frame.

Optionally, the hinge part is a first hinge seat; one end of the lock mechanism facing to the first hinge seat is provided with a second hinge seat; and the first hinge seat and the second hinge seat are hinged through a hinge shaft.

Optionally, the mounting frame is provided with a recessed sinking groove that is recessed towards the hinge part; a bottom wall of the sinking groove is provided with a snap-in hole; and the mating part is the snap-in hole.

Optionally, the expansion card assembly comprises an expansion card and a stop piece; the stop piece is vertically fixed on the expansion card; the mounting frame is provided with a side abutment surface, a top abutment surface, and a vertical plate; the vertical plate is vertically arranged on the top abutment surface; the mating part is located on the vertical plate; the expansion card is abutted against the side abutment surface; and the lock mechanism presses the stop piece against the top abutment surface.

The server provided in an embodiment of the present application includes any one of the above locking and fixing device.

Other features and advantages of the present application will be described in the following description, and partly become obvious from the description, or understood by implementing the present application. The purpose and other advantages of the present application can be realized and obtained through the structures specifically pointed out in the written description, claims, and drawings.

### BRIEF DESCRIPTION OF THE DRAWINGS

The accompanying drawings are included to provide a further understanding of the application, and are incorporated in and constitute a part of this specification, illustrate embodiments of the application and together with the example serve to explain the principles of the application.

FIG. 1 is a partially schematic structural diagram of a locked state of a locking and fixing device according to one embodiment of the present application;

FIG. 2 is a partially schematic structural diagram of an unlocked state of the locking and fixing device shown in FIG. 1;

FIG. 3 is a partially schematic structural diagram after a mounting frame and a lock mechanism in FIG. 1 are assembled;

FIG. 4 is a schematic exploded structural diagram of a lock mechanism in FIG. 1;

FIG. 5 and FIG. 6 are schematic three-dimensional structural diagrams of a fixing member in FIG. 4; and

FIG. 7 and FIG. 8 are schematic three-dimensional structural diagrams of a lock catch in FIG. 4.

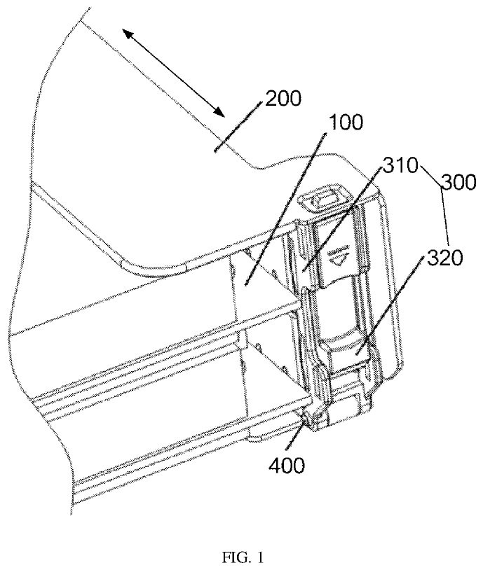

Correspondence relationships between reference numerals and names of components in FIG. 1 to FIG. 8 are as follows:

100: expansion card assembly; 110: expansion card; 120: stop piece; 200: mounting frame; 210: first hinge seat; 220: snap-in hole; 230: side abutment surface; 240: top abutment surface; 250: vertical plate; 251: sinking groove; 300: lock mechanism; 310: fixing member; 311: second hinge seat; 312: stop plate; 313: elongated accommodating slot; 314: through hole; 315: guide elongated slot; 316: elastic convex rib; 320: lock catch; 321: spring bolt; 322: mounting slot; 323: guide block; 324: operation part; 325: operation indication identifier; 326: reinforcing rib; 330: elastic member; and 400: hinge shaft.

### DETAILED DESCRIPTION

To make the objects, technical solutions and advantages of the present application more apparent, embodiments of the present application will be described in detail below with reference to the accompanying drawings. It should be noted that the embodiments and features of the embodiments in the present application may be arbitrarily combined with each other without conflict.

The following description illustrates many specific details in order to fully understand the present application. However, the present application can also be implemented in different other ways than those described here. Therefore, the protection scope of the present application is not limited by the specific embodiments disclosed below.

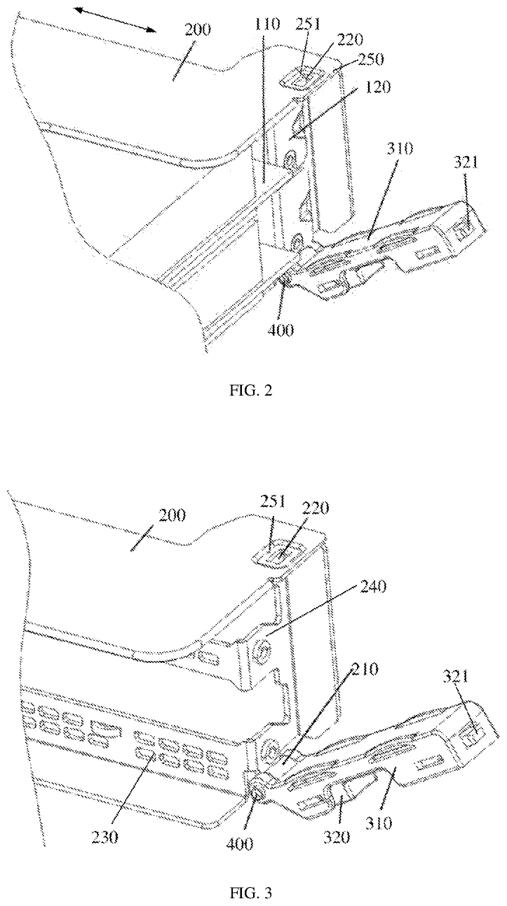

A server provided in an embodiment of the present application includes a locking and fixing device. As shown in FIG. 1 to FIG. 8, the locking and fixing device includes a mounting frame 200 and an expansion card assembly 100. The expansion card assembly 100 is mounted on the mounting frame 200 (the arrow in FIG. 1 and FIG. 2 indicates directions for assembling the expansion card assembly 100 to and removing same from the mounting frame 200). The locking and fixing device further includes a lock mechanism 300. The mounting frame 200 is provided with a hinge part 210 and a mating part 220. One end of the lock mechanism 300 facing the hinge part 210 is hinged to the hinge part 210, and one end of the lock mechanism 300 facing away from the hinge part 210 is openably and closably locked on the mating part 220, so as to lock the mounting frame 200 and the expansion card assembly 100 together.

According to the server, the mounting frame 200 is provided with the hinge part 210 and the mating part 220; and one end of the lock mechanism 300 facing the hinge part 210 is hinged to the hinge part 210, and one end facing away from the hinge part 210 is openably and closably locked on the mating part 220, so as to lock the mounting frame 200 and the expansion card assembly 100 together. The mounting frame 200 and the expansion card assembly 100 are removed by unlocking the lock mechanism 300 only; it is more convenient to assemble, fix, and remove the mounting frame 200 and the expansion card assembly 100; furthermore, no screws are used in the assembling, fixing, and removing processes, so that the server does not have the problems of looseness, fall off, losing, and breakage of screws; and the usability of the server can be better maintained.

As shown in FIG. 1 to FIG. 3, the expansion card assembly 100 includes an expansion card 110 and a stop piece 120; the stop piece 120 is vertically fixed beside the expansion card 110; the mounting frame 200 is provided with a side abutment surface 230, a top abutment surface 240, and a vertical plate 250; the vertical plate 250 is vertically arranged on the top abutment surface 240; the hinge part 210 is opposite to the vertical plate 250; the side abutment surface 230 is located between the hinge part 210 and the vertical plate 250 and extends away from the lock mechanism 300; the mating part 220 is located on the vertical plate 250; the expansion card 110 is abutted against the side abutment surface 230; and the lock mechanism 300 presses the stop piece 120 against the top abutment surface 240, so as to lock the mounting frame 200 and the stop piece 120 together, that is, to assemble and fix the mounting frame 200, the expansion card 110, and the stop piece 120 together.

Preferably, as shown in FIG. 1 to FIG. 3, a recessed sinking groove 251 that is recessed towards the hinge part 210 is formed in the mounting frame 250; a snap-in hole 220 is formed in a bottom wall of the sinking groove 251; and the mating part 220 is the snap-in hole 220. As shown in FIG. 1 to FIG. 8, the lock mechanism 300 includes: a fixing member 310, one end of which facing the hinge part 210 is hinged to the hinge part 210; a lock catch 320 movably mounted on the fixing member 310 and assembled with the fixing member 310, wherein one end of the lock catch 320 facing away from the hinge part 210 is provided with a spring bolt 321, and the spring bolt 321 extends into the snap-in hole 220 to achieve locking; and an elastic member 330 for resetting arranged between the fixing member 310 and the lock catch 320, thus keeping the spring bolt 321 extending into the snap-in hole 220, ensuring that the mounting frame 200 and the expansion card assembly 100 are firmly fixed together, and preventing the spring bolt 321 from falling out of the snap-in hole 220 to cause the mounting frame 200 and the expansion card assembly 100 to be loosened from each other. The elastic member 330 may be configured to be a spiral spring.

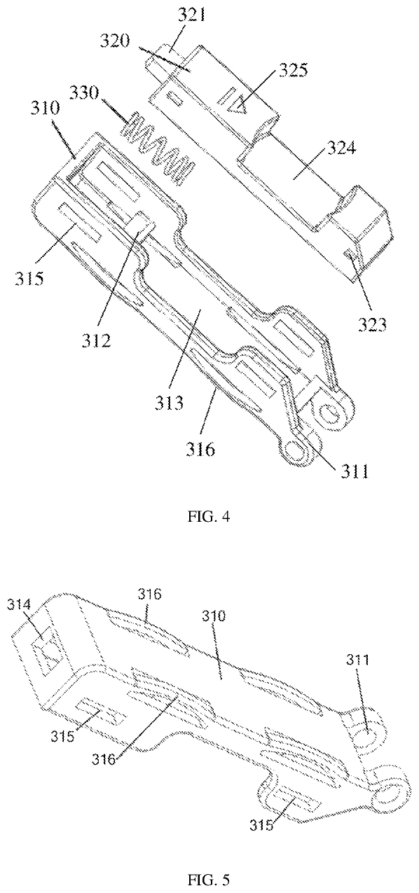

Specifically, as shown in FIG. 4 to FIG. 8, a side surface of the lock catch 320 facing the fixing member 310 is provided with a mounting slot 322; the elastic member 330 is located in the mounting slot 322; a protruding stop plate 312 is arranged on the fixing member 310; the stop plate 312 extends into the mounting slot 322; and one end of the elastic member 330 facing to the spring bolt 321 is abutted against a slot wall of the mounting slot 322, and one end facing away from the spring bolt 321 is abutted against the stop plate 312. The side surface of the lock catch 320 facing the fixing member 310 is further provided with a reinforcing rib 326.

Preferably, as shown in FIG. 4 to FIG. 8, a side surface of the fixing member 310 facing to the lock catch 320 is provided with an elongated accommodating slot 313; the lock catch 320 is movably mounted in the elongated accommodating slot 313; a through hole 314 is formed in a side wall of one end of the elongated accommodating slot 313 facing away from the hinge part 210; the spring bolt 321 extends out of the through hole 314 into the snap-in hole 220; a side wall of the end of the elongated accommodating slot 313 facing away from the hinge part 210 also limits the motion of one side of the lock catch 320 facing to the snap-in hole 220.

Further, as shown in FIG. 4 to FIG. 8, a guide rail elongated slot 315 is formed in a side wall of the elongated accommodating slot 313 adjacent to the through hole 314; a guide block 323 is arranged on the lock catch 320; and the guide block 323 extends into the guide rail elongated slot 315 to guide a reciprocating linear movement of the lock catch 320, and to limit the motion of the lock catch 320 at the same time. In addition, there may be two or four groups of the guide rail elongated slots 315 and the guide block 323 that are symmetrically disposed, which can achieve the objective of the present application. The purpose does not depart from the design idea of the present application. The descriptions thereof are omitted here and shall all fall within the protection scope of the present application.

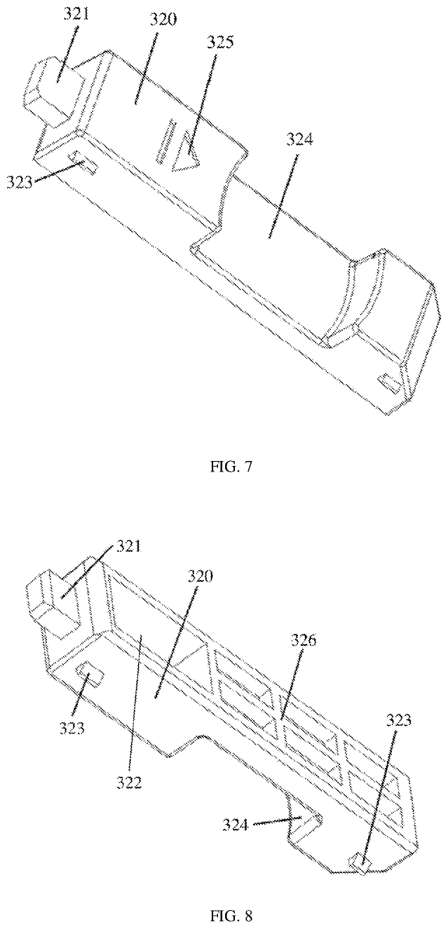

Specifically, as shown in FIG. 4, FIG. 7, and FIG. 8, the side surface of the lock catch 320 facing away from the fixing member 310 is provided with an operation part 324 and an operation indication identifier 325. The operation part 324 is used for driving an unlocking action of the lock catch 320, and the operation indication identifier 325 is used for indicating a moving direction during unlocking of the lock catch 320. The operation part 324 can be embodied as a boss or a groove. The operation indication identifier 325 can be embodied as an indication arrow slot, or an indication arrow paste, and the like, which can achieve the objective of the present application. The purpose does not depart from the design idea of the present application. The descriptions thereof are omitted here and shall all fall within the protection scope of the present application.

In order to better insert the spring bolt 321 in the snap-in hole 220, the side surface of the spring bolt 321 facing the fixing member 310 is configured as a guide bevel. In order to better assemble the guide block 323 into the guide rail elongated slot 315, a side surface of the guide block 323 facing the fixing member 310 is also configured as a guide bevel.

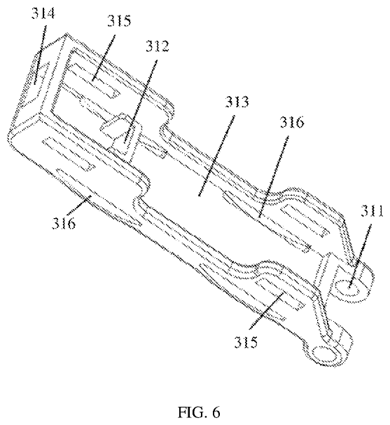

Specifically, as shown in FIG. 5 and FIG. 6, a side surface of the fixing member 310 facing away from the lock catch 320 is provided with an elastic convex rib 316, and the elastic convex rib 316 presses the stop piece 120 against the mounting frame 200 by means of elastic deformation, so as to better fix the mounting frame 200 and the stop piece 120 and prevent the stop piece 120 from being loosened. After the lock catch 320 is unlocked, the elastic convex rib 316 can further open the lock mechanism 300 by itself, which is more favorable for quickly opening the lock mechanism 300. Specifically, as shown in FIG. 3, FIG. 5, and FIG. 6, the hinge part 210 is embodied as a first hinge seat 210; one end of the fixing member 310 facing to the first hinge seat 210 is provided with a second hinge seat 311. The first hinge seat 210 and the second hinge seat 311 are hinged through a hinge shaft 400.

Specifically, both of the fixing member 310 and the lock catch 320 are plastic members.

As shown in FIG. 1 and FIG. 2, the locking process for the expansion card 110, the stop piece 120, and the mounting frame 200 is as follows:

The expansion card 110 and the stop piece 120 are first assembled into the expansion card assembly 100, and the expansion card assembly 100 is then assembled on the mounting frame 200; the lock mechanism 300 is locked on the mounting frame 200 (the lock mechanism 300 is directly pressed to the side with the mounting frame 200, and the spring bolt 321 first retracts to the through hole under the action of the guide bevel and then extends out of the through hole into the snap-in hole). The locking process of the lock mechanism 300 can also be as follows: The lock catch 320 is driven to move in the fixing member 310 towards the side with the hinge part 210, so that the spring bolt 321 retracts into the through hole 314; after the lock mechanism 300 is rotatably fastened on the mounting frame 200, the lock catch 320 is loosened; the lock catch 320 enables the spring bolt 321 to extend into the snap-in hole 220 under the action of the elastic member 330; and at this time, the elastic convex rib 316 presses the stop piece 120 against the top abutment surface 240 to lock and fix the expansion card 110, the stop piece 120, and the mounting frame 200.

As shown in FIG. 1 and FIG. 2, the unlocking process for the expansion card 110, the stop piece 120, and the mounting frame 200 is as follows:

According to an indication direction of the operation indication identifier 325, the lock catch 320 is pushed to move towards the hinge part 210 by driving the operation part 324, so that the spring bolt 321 retracts into the through hole 314 from the snap-in hole 220; the lock mechanism 300 is rotatably opened; and after the lock catch 320 is loosened, the lock catch 320 moves away from the hinge part 210 under the action of an elastic force of the elastic member 330, so that the spring bolt 321 then extends out of the through hole 314.

In conclusion, according to the server provided in the embodiment of the present application, the mounting frame is provided with the hinge part 210 and the mating part 220; one end of the lock mechanism facing to the hinge part 210 is hinged to the hinge part 210, and one end facing away from the hinge part 210 is locked on the mating part 220 in a manner of being opened and closed, so as to lock the mounting frame and the expansion card assembly together; the mounting frame and the expansion card assembly are removed by unlocking the lock mechanism only; it is more convenient to assemble, fix, and remove the mounting frame and the expansion card assembly; furthermore, no screws are used in the assembling, fixing, and removing processes, so that the server does not have the problems of looseness, fall off, losing, and breakage of screws; and the usability of the locking and fixing device can be better maintained.

In the description of the present application, the terms “mount”, “connect”, “connection”, “fix”, etc. should be understood in a broad sense, for example, “connection” may be a fixed connection, a detachable connection, an integral connection, a direct connection, or a connection by means of an intermediate. For those of ordinary skill in the art, the specific meanings of the above terms in the present application can be understood according to specific situations.

In the description of this specification, descriptions of the terms such as “one embodiment”, “some embodiments”, “specific examples” mean that specific features, structures, materials or characteristics described in combination with the embodiments or examples are included in at least one embodiment or example of the present application. In the present specification, schematic representations of the above terms do not necessarily refer to the same embodiment or example. Furthermore, the described specific features, structures, materials or features can be combined in any suitable manner in one or more embodiments or examples.

Even although the embodiments disclosed herein are described above, the above description are merely embodiments for the convenience of understanding the present application, but not constructed as limiting the present application. Any person skilled in the art may make any modifications and variations in the implementation form and details without departing from the spirit and scope of the present application. Moreover, the protection scope of the present application shall be still subjected to the scope as defined in the appended claims.

1. A locking and fixing device, comprising a mounting frame and an expansion card assembly, wherein the expansion card assembly is mounted on the mounting frame, and the locking and fixing device further comprises:
a lock mechanism, wherein the mounting frame is provided with a hinge part and a mating part, a first and end of the lock mechanism facing the hinge part is hinged to the hinge part, and a second end of the lock mechanism facing away from the hinge part is openably and closably locked on the mating part, so as to lock the mounting frame and the expansion card assembly together.

2. The locking and fixing device according to claim 1, wherein the lock mechanism comprises:
a fixing member, wherein a first end of the fixing member facing the hinge part is hinged to the hinge part;
a lock catch movably mounted on the fixing member and assembled with the fixing member, wherein a first end of the lock catch facing away from the hinge part is provided with a spring bolt, and the spring bolt and the mating part are locked with each other; and
an elastic member for resetting, wherein the elastic member is arranged between the fixing member and the lock catch.

3. The locking and fixing device according to claim 2, wherein a side surface of the lock catch facing the fixing member is provided with a mounting slot, the elastic member is located in the mounting slot, a protruding stop plate is arranged on the fixing member, the protruding stop plate extends into the mounting slot, a first end of the elastic member facing the spring bolt abuts against a slot wall of the mounting slot, and a second end of the elastic member facing away from the spring bolt against the protruding stop plate.

4. The locking and fixing device according to claim 2, wherein a side surface of the fixing member facing the lock catch is provided with an elongated accommodating slot, the lock catch is movably mounted in the elongated accommodating slot, a through hole is defined in a side wall of a first end of the elongated accommodating slot facing away from the hinge part, and the spring bolt extends out of the through hole and is locked on the mating part.

5. The locking and fixing device according to claim 4, wherein a guide rail elongated slot is defined in a side wall of the elongated accommodating slot adjacent to the through hole, a guide block is provided on the lock catch, and the guide block extends into the guide rail elongated slot to guide a reciprocating linear movement of the lock catch.

6. The locking and fixing device according to claim 2, wherein a side surface of the lock catch facing away from the fixing member is provided with an operation part and an operation indication identifier.

7. The locking and fixing device according to claim 2, wherein a side surface of the fixing member facing away from the lock catch is provided with an elastic convex rib, and the elastic convex rib presses the expansion card assembly against the mounting frame.

8. The locking and fixing device according to claim 1, wherein the hinge part is a first hinge seat, the first end of the lock mechanism facing the first hinge seat is provided with a second hinge seat, and the first hinge seat and the second hinge seat are hinged through a hinge shaft.

9. The locking and fixing device according to claim 1, wherein the mounting frame is provided with a recessed sinking groove that is recessed towards the hinge part, a bottom wall of the recessed sinking groove is provided with a snap-in hole, and the mating part is the snap-in hole.

10. The locking and fixing device according to claim 1, wherein the expansion card assembly comprises an expansion card and a stop piece, the stop piece is vertically fixed on the expansion card, the mounting frame is provided with a side abutment surface, a top abutment surface, and a vertical plate, the vertical plate is vertically arranged on the top abutment surface, the mating part is located on the vertical plate, the expansion card abuts against the side abutment surface, and the lock mechanism presses the stop piece against the top abutment surface.

11. A server, comprising a locking and fixing device, the locking and fixing device comprising a mounting frame and an expansion card assembly, wherein the expansion card assembly is mounted on the mounting frame, and the locking and fixing device further comprises:
a lock mechanism, wherein the mounting frame is provided with a hinge part and a mating part, a first end of the lock mechanism facing the hinge part is hinged to the hinge part, and a second end of the lock mechanism facing away from the hinge part is openably and closably locked on the mating part, so as to lock the mounting frame and the expansion card assembly together.

12. The server according to claim 11, wherein the lock mechanism comprises:
a fixing member, wherein a first end of the fixing member facing the hinge part is hinged to the hinge part;
a lock catch movably mounted on the fixing member and assembled with the fixing member, wherein a first end of the lock catch facing away from the hinge part is provided with a spring bolt, and the spring bolt and the mating part are locked with each other; and
an elastic member for resetting, wherein the elastic member is arranged between the fixing member and the lock catch.

13. The server according to claim 12, wherein a side surface of the lock catch facing the fixing member is provided with a mounting slot, the elastic member is located in the mounting slot, a protruding stop plate is arranged on the fixing member, the protruding stop plate extends into the mounting slot, a first end of the elastic member facing the spring bolt abuts against a slot wall of the mounting slot, and a second end of the elastic member facing away from the spring bolt abuts against the protruding stop plate.

14. The server according to claim 12, wherein a side surface of the fixing member facing the lock catch is provided with an elongated accommodating slot, the lock catch is movably mounted in the elongated accommodating slot, a through hole is defined in a side wall of a first end of the elongated accommodating slot facing away from the hinge part, and the spring bolt extends out of the through hole and is locked on the mating part.

15. The server according to claim 14, wherein a guide rail elongated slot is defined in a side wall of the elongated accommodating slot adjacent to the through hole, a guide block is provided on the lock catch, and the guide block extends into the guide rail elongated slot to guide a reciprocating linear movement of the lock catch.

16. The server according to claim 12, wherein a side surface of the lock catch facing away from the fixing member is provided with an operation part and an operation indication identifier.

17. The server according to claim 12, wherein a side surface of the fixing member facing away from the lock catch is provided with an elastic convex rib, and the elastic convex rib presses the expansion card assembly against the mounting frame.

18. The server according to claim 11, wherein the hinge part is a first hinge seat, the first end of the lock mechanism facing the first hinge seat is provided with a second hinge seat, and the first hinge seat and the second hinge seat are hinged through a hinge shaft.

19. The server according to claim 11, wherein the mounting frame is provided with a recessed sinking groove that is recessed towards the hinge part, a bottom wall of the recessed sinking groove is provided with a snap-in hole, and the mating part is the snap-in hole.

20. The server according to claim 11, wherein the expansion card assembly comprises an expansion card and a stop piece, the stop piece is vertically fixed on the expansion card, the mounting frame is provided with a side abutment surface, a top abutment surface, and a vertical plate, the vertical plate is vertically arranged on the top abutment surface, the mating part is located on the vertical plate, the expansion card abuts against the side abutment surface, and the lock mechanism presses the stop piece against the top abutment surface.
